(19) United States
(12) Patent Application Publication
(10) Pub. No.: US 2025/0167783 A1
(43) Pub. Date: May 22, 2025

(54) DRIVING APPARATUS

(71) Applicant: FUJI ELECTRIC CO., LTD., Kanagawa (JP)

(72) Inventor: Masashi AKAHANE, Matsumoto-city (JP)

(21) Appl. No.: 18/923,530

(22) Filed: Oct. 22, 2024

(30) Foreign Application Priority Data
Nov. 22, 2023 (JP) 2023-198558
Apr. 12, 2024 (JP) 2024-064791

(51) Int. Cl. H03K 17/687; H03K 17/08

(52) U.S. Cl. CPC H03K 17/6871; H03K 2017/0806; H03K 2217/0063; H03K 2217/0072

(57) ABSTRACT

Provided is a driving apparatus of a power semiconductor, including: a first circuit; a second circuit; a state signal generation unit that generates a first state signal indicating a state of the first circuit with a digital value of multiple bits; and a communication control unit that controls an output period in which the first circuit outputs the first state signal based on a loaded-state signal indicating a transition timing of ON/OFF of the power semiconductor.

The contents of the following patent application(s) are incorporated herein by reference:
NO. 2023-198558 filed in JP on Nov. 22, 2023 and
NO. 2024-064791 filed in JP on Apr. 12, 2024.

### BACKGROUND

### 1. Technical Field

The present invention relates to a driving apparatus.

### 2. Related Art

Conventionally, in a driving apparatus which drives a target apparatus such as a power semiconductor, a configuration which outputs a state such as a temperature of a driving apparatus is known (for example, refer to Patent document 1 to 3).
Patent document 1: Japanese Patent Application Publication No. 2014-93903
Patent document 2: Japanese Patent Application Publication No. 2009-258016
Patent document 3: U.S. Pat. No. 5,210,846 Specification

### BRIEF DESCRIPTION OF THE DRAWINGS

FIG. 1 shows an example of a power supply apparatus 300 according to one embodiment of the present invention.

FIG. 2 shows an example of an isolation device 32.

FIG. 3 is a block diagram indicating a configuration example of a high side circuit 10.

FIG. 4 is a block diagram indicating a configuration example of a low side circuit 50.

FIG. 5 is a block diagram indicating a configuration example of a state signal generation unit 20 and an input circuit 62.

FIG. 6 is a timing chart describing an exemplary operation of the state signal generation unit 20 indicated in FIG. 5.

FIG. 7 is a timing chart describing an exemplary operation of the input circuit 62 indicated in FIG. 5.

FIG. 8 is a state machine indicating a state transition of the state signal generation unit 20.

FIG. 9 is a state machine indicating a state transition of the input circuit 62.

FIG. 10 shows another example of a transmission unit 30.

FIG. 11 shows a configuration example of a level shift circuit 34.

FIG. 12 shows another example of a driving apparatus 100.

FIG. 13 shows an example of signal waveforms of a control signal DRVIN, a clock signal CLK, and an output voltage VOUT.

FIG. 14 is a block diagram indicating a configuration example of the high side circuit 10 indicated in FIG. 12.

FIG. 15 is a block diagram indicating a configuration example of the low side circuit 50 indicated in FIG. 12.

FIG. 16 is a block diagram indicating a configuration example of the state signal generation unit 20 and the input circuit 62 in the driving apparatus 100 indicated in FIG. 12 to FIG. 15.

FIG. 17 shows an example of a high voltage device 33.

FIG. 18 shows an example of an output unit 74.

FIG. 19 shows an example of an input circuit 72.

FIG. 20 shows an example of a time waveform of each signal in the driving apparatus 100.

FIG. 21 is a block diagram indicating another configuration example of the state signal generation unit 20 and the input circuit 62 in the driving apparatus 100 indicated in FIG. 12 to FIG. 15.

FIG. 22 shows an example of an input/output circuit 93.

### DESCRIPTION OF EXEMPLARY EMBODIMENTS

Hereinafter, embodiments of the present invention will be explained. However, the following embodiments do not limit the invention according to the claims. In addition, not all of the combinations of features described in the embodiments are essential to the solutions of the invention. Note that in the present specification and the diagrams, elements having substantially the same function and architecture are denoted with a same reference sign to omit duplicated descriptions, and illustrations of elements that are not directly related to the present invention will be omitted. Further, in one diagram, elements having the same functions and architecture are denoted by a representative reference sign, and other reference signs for the elements may be omitted.

In the present specification, a case where a term such as “same” or “equal” is mentioned may include a case where an error due to a variation in manufacturing or the like is included. The error is, for example, within 10%.

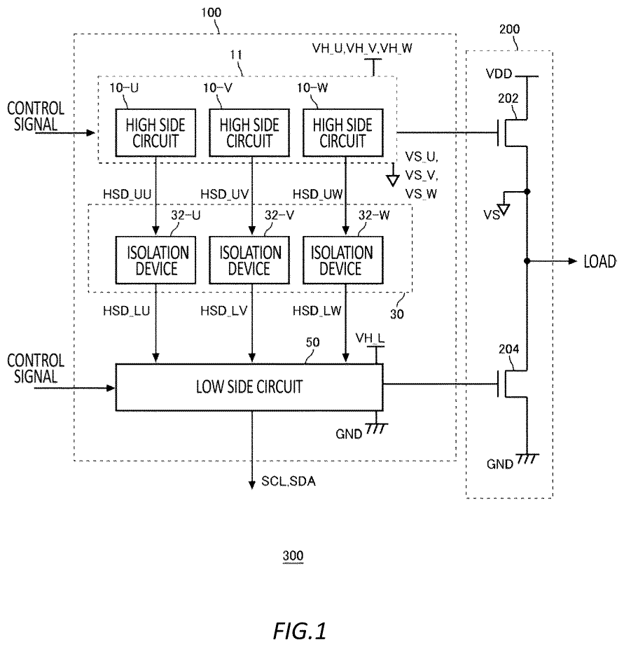

FIG. 1 shows an example of a power supply apparatus 300 according to one embodiment of the present invention. The power supply apparatus 300 supplies electrical power to a load. The load is a circuit that is provided on a vehicle or an industrial robot, for example, but is not limited thereto. The power supply apparatus 300 includes a driving apparatus 100, and an output apparatus 200.

The output apparatus 200 supplies electrical power to the load. The output apparatus 200 includes a power semiconductor 202, and a power semiconductor 204. For example, the power semiconductor 202 and the power semiconductor 204 may be an IGBT or a MOSFET, or may be another device. The power semiconductor 202 and the power semiconductor 204 of the present example are provided in series between a high voltage wiring VDD and a ground potential GND.

The power semiconductor 202 of the present example is a high side MOSFET having a drain terminal that is connected to the high voltage wiring VDD, and a source terminal that is connected to the load. The power semiconductor 204 is a low side MOSFET having a drain terminal that is connected to the load, and a source terminal that is connected to the ground potential GND. The output apparatus 200 may have a plurality of pairs of power semiconductor 202 and power semiconductor 204. For example, the output apparatus 200 may be a three-phase circuit having three pairs of power semiconductor 202 and power semiconductor 204.

The driving apparatus 100 drives the power semiconductor 202 and the power semiconductor 204. The driving apparatus 100 of the present example controls switching operations of the power semiconductor 202 and the power semiconductor 204. The driving apparatus 100 includes a high side circuit unit 11, a transmission unit 30, and a low side circuit 50.

The high side circuit unit 11 controls switching operation of the power semiconductor 202 based on a control signal that is input. A second power supply voltage VH_U and a second reference voltage VS_U are applied to the high side circuit unit 11. The high side circuit unit 11 operates based on the second power supply voltage VH_U and the second reference voltage VS_U. The second reference voltage VS_U is a voltage higher than a first reference voltage GND of the low side circuit 50. The second reference voltage VS_U of the present example is a voltage of the source terminal of the power semiconductor 202.

The control signal that is input to the high side circuit unit 11 is a signal that controls a timing at which the power semiconductor 202 is to be switched. For example, the control signal is a signal that is at H level during a period in which the power semiconductor 202 should be in an ON state, and that is at L level during a period in which the power semiconductor 202 should be in an OFF state.

The high side circuit unit 11 applies a drive signal having a waveform corresponding to the control signal to the power semiconductor 202. The drive signal may be input to the gate terminal of the power semiconductor 202. The drive signal may have a same logical value pattern as that of the control signal. The high side circuit unit 11 may output a drive signal of a level corresponding to the second power supply voltage VH_U during the period in which the power semiconductor 202 should be turned on, and may output a drive signal of a level corresponding to the second reference voltage VS_U during the period in which the power semiconductor 202 should be turned off.

The high side circuit unit 11 has one or more high side circuits 10 in response to the number of the power semiconductor 202 that should be controlled. The high side circuit unit 11 of the present example has three high side circuits 10-U, 10-V, and 10-W. Each high side circuit 10 outputs a drive signal of a corresponding power semiconductor 202. Each power supply may be connected to each high side circuit 10. Each of the second power supply voltage VH_U, VH_V, and VH_W is applied to each high side circuit 10. Each of the second reference voltage VS_U, VS_V, and VS_W is applied to each high side circuit 10.

The low side circuit 50 controls switching operation of the power semiconductor 204 based on a control signal that is input. A first power supply voltage VH_L and a first reference voltage GND are applied to the low side circuit 50. The low side circuit 50 operates based on the first power supply voltage VH_L and the first reference voltage GND. The first power supply voltage VH_L is lower than the second power supply voltage VH_U. The first reference voltage GND is lower than the second reference voltage VS. The first reference voltage GND may be a ground voltage.

The control signal that is input to the low side circuit 50 is a signal that controls a timing at which the power semiconductor 204 is to be switched. For example, the control signal is a signal that is at H level during a period in which the power semiconductor 204 should be in an ON state, and that is at L level during a period in which the power semiconductor 204 should be in an OFF state.

The low side circuit 50 applies a drive signal having a waveform corresponding to the control signal to the power semiconductor 204. The drive signal may be input to the gate terminal of the power semiconductor 204. The drive signal may have a same logical value pattern as that of the control signal. The low side circuit 50 may output a drive signal of a level corresponding to the first power supply voltage VH_L during the period in which the power semiconductor 204 should be turned on, and may output a drive signal of a level corresponding to the first reference voltage GND during the period in which the power semiconductor 204 should be turned off. The low side circuit 50 outputs one or more drive signals in response to the number of the power semiconductor 204 that should be controlled.

The low side circuit 50 outputs a state signal SCL indicating a state of the driving apparatus 100. The state signal SCL is a digital signal. The state signal SCL may be output to a controller that controls the driving apparatus 100. The controller may control the driving apparatus 100 based on the state signal SCL. For example, the controller may stop the operation of the driving apparatus 100 when an abnormality occurs on the driving apparatus 100.

The state signal SCL includes information indicating a state of the high side circuit 10. The state signal SCL may further include information indicating a state of the low side circuit 50. The low side circuit 50 of the present example outputs a state signal SCL including both the state of the high side circuit 10 and the state of the low side circuit 50. The state signal SCL may include information indicating at least any value of a temperature in a predetermined place of each circuit, a current flowing in the predetermined place, and a voltage that is applied to the predetermined place. The state signal SCL may include information indicating whether at least any of the temperature, the current, and the voltage of each circuit is within a predetermined allowable range.

Each high side circuit 10 generates a high side state signal HSD_U indicating the state of the high side circuit 10 with a digital value of multiple bits. The high side state signal HSD_U of the present example is a signal that is a voltage corresponding to the second power supply voltage VH_U during a period of logic H, and that is a voltage corresponding to the second reference voltage VS during a period of logic L. Herein, a logical value 1 may be referred to as logic H, and a logical value 0 may be referred to as logic L.

In the example of FIG. 1, a high side circuit 10-U, 10-V, and 10-W generates a high side state signal HSD_UU, HSD_UV, and HSD_UW. Each high side state signal HSD_U includes information indicating at least any of a temperature, a current, and a voltage in a corresponding high side circuit 10, as well as whether those values are within an allowable range.

A transmission unit 30 generates a high side state signal HSD_L that is obtained by converting a second reference voltage VS of the high side state signal HSD_U into a first reference voltage GND. The transmission unit 30 of the present example converts the high side state signal HSD_UU, HSD_UV and HSD_UW into a high side state signal HSD_LU, HSD_LV, and HSD_LW. The high side state signal HSD_LU, HSD_LV, and HSD_LW have same logical value patterns of the high side state signals HSD_UU, HSD_UV, and HSD_UW, and may be signals each having a same bit period. The bit period is a period occupied by one bit of information in a signal.

The high side state signal HSD_L of the present example is a signal that is a voltage corresponding to the second reference voltage VS during the period of logic L. The high side state signal HSD_L may be a voltage corresponding to the first power supply voltage VH_L or may be another voltage during the period of logic H.

The transmission unit 30 transmits the high side state signal HSD_L to a low side circuit 50. The low side circuit 50 outputs a state signal SCL including information included in the high side state signal HSD_L.

The second reference voltage VS in the high side circuit 10 changes in response to an operational state of a power semiconductor 202 and a power semiconductor 204. Therefore, a reference voltage of the high side state signal HSD_U varies. According to the present example, the transmission unit 30 converts the reference voltage of the high side state signal HSD into a reference voltage that is suitable for a process of the low side circuit 50. Therefore, the low side circuit 50 can easily process the high side state signal HSD. In addition, the low side circuit 50 can generate a state signal SCL including both a state of the low side circuit 50 and a state of the high side circuit 10. Therefore, the state of the high side circuit 10 can be informed outside in a simple configuration.

The transmission unit 30 of the present example has one or more isolation devices 32 in response to one or more high side circuits 10. The isolation device 32 converts and transmits the reference voltage of the high side state signal HSD in a state in which the high side circuit 10 and the low side circuit 50 are electrically insulated.

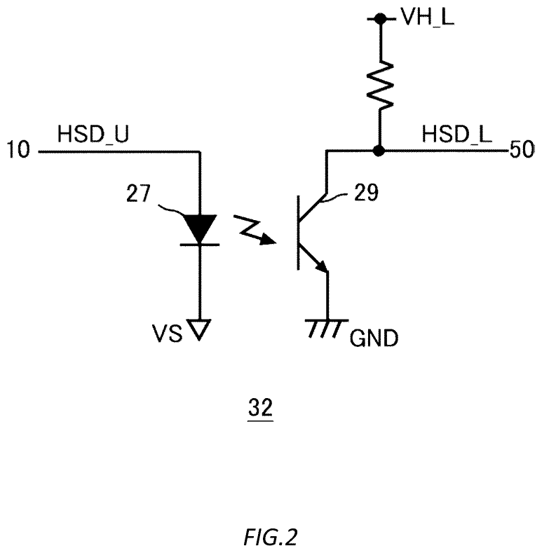

FIG. 2 shows an example of an isolation device 32. The isolation device 32 of the present example is a photocoupler which has a light emitting device 27 and a light receiving device 29. The light emitting device 27 emits light according to the high side state signal HSD_U. The light emitting device 27 is a light-emitting diode, for example. The second reference voltage VS is applied to a cathode terminal of the light emitting device 27. The high side state signal HSD_U is applied to an anode terminal of the light emitting device 27.

The light receiving device 29 receives a light emission signal from the light emitting device 27, to generate the high side state signal HSD_L. The light receiving device 29 is a phototransistor, for example. The first reference voltage GND is applied to an emitter terminal of the light receiving device 29. A voltage of a collector terminal of the light receiving device 29 is output as the high side state signal HSD_L. The light receiving device 29 may generate a high side state signal HSD_L that is a predetermined high voltage during a period in which a light of an intensity greater than or equal to a predetermined intensity is received, and that is a first reference voltage GND during a period in which the light of the intensity greater than or equal to the predetermined intensity is not received. The high voltage of the high side state signal HSD_L may be the same as the first power supply voltage VH_L, or may be different.

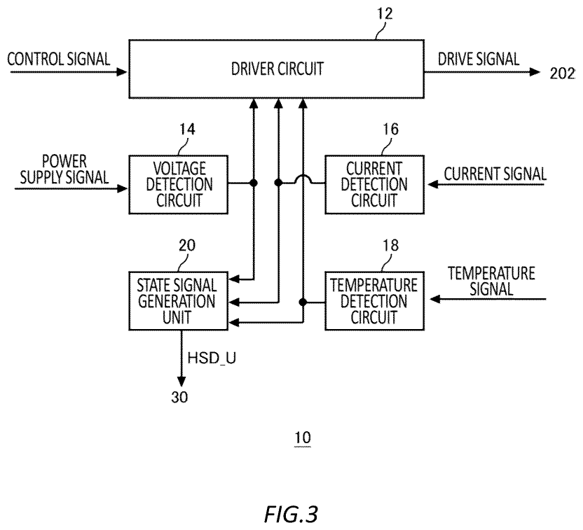

FIG. 3 is a block diagram indicating a configuration example of a high side circuit 10. The high side circuit 10 of the present example has a driver circuit 12, a voltage detection circuit 14, a current detection circuit 16, a temperature detection circuit 18, and a state signal generation unit 20. The driver circuit 12 outputs a drive signal that controls a power semiconductor 202 based on a control signal that is input from a controller outside, and the like.

The voltage detection circuit 14 detects a voltage at a predetermined place in the high side circuit 10. For example, the voltage detection circuit 14 may detect a second power supply voltage VH_U at a place to which the second power supply voltage VH_U is applied. The voltage detection circuit 14 may determine whether a difference between the voltage that is detected and a reference value is within an allowable range. The voltage detection circuit 14 may inform the driver circuit 12 the determination result. The driver circuit 12 may control the power semiconductor 202 to be in an OFF state when the difference between the voltage that is detected by the voltage detection circuit 14 and the reference value is not within an allowable range.

The current detection circuit 16 detects a current flowing in a predetermined place in the high side circuit 10. For example, the current detection circuit 16 may detect a current flowing from the driver circuit 12 to the power semiconductor 202. The current detection circuit 16 may determine whether a difference between the current that is detected and a reference value is within an allowable range. The current detection circuit 16 may inform the driver circuit 12 the determination result. The driver circuit 12 may control the power semiconductor 202 to be in an OFF state when the difference between the current that is detected by the current detection circuit 16 and the reference value is not within an allowable range.

The temperature detection circuit 18 detects a temperature at a predetermined place in the high side circuit 10. For example, the temperature detection circuit 18 may detect a temperature of the driver circuit 12. The temperature detection circuit 18 may determine whether a difference between the temperature that is detected and a reference value is within an allowable range. The temperature detection circuit 18 may inform the driver circuit 12 the determination result. The driver circuit 12 may control the power semiconductor 202 to be in an OFF state when the difference between the temperature that is detected by the temperature detection circuit 18 and the reference value is not within an allowable range.

The voltage detection circuit 14, the current detection circuit 16, and the temperature detection circuit 18 may detect a voltage, a current, and a temperature of an output apparatus 200. The voltage detection circuit 14, the current detection circuit 16, and the temperature detection circuit 18 may respectively detect a voltage, a current, and a temperature of a power semiconductor 202.

The state signal generation unit 20 generates a high side state signal HSD_U indicating a state of the high side circuit 10 based on at least one of the voltage that is detected by the voltage detection circuit 14, the current that is detected by the current detection circuit 16, and the temperature that is detected by the temperature detection circuit 18. The high side state signal HSD_U may include at least any value of the voltage, the current, and the temperature (V, A, ° C.), and may include a determination result obtained in at least one of the voltage detection circuit 14, the current detection circuit 16, and the temperature detection circuit 18. The high side state signal HSD_U may include information indicating another state of the high side circuit 10. The high side state signal HSD_U may include information related to a frequency of the voltage or the current at the high side circuit 10, may include information related to a cumulative running time, or may include another information. The high side state signal HSD_U may include information indicating a state of the high side circuit 10 at the current moment, or may include information indicating a state of the high side circuit 10 in the past.

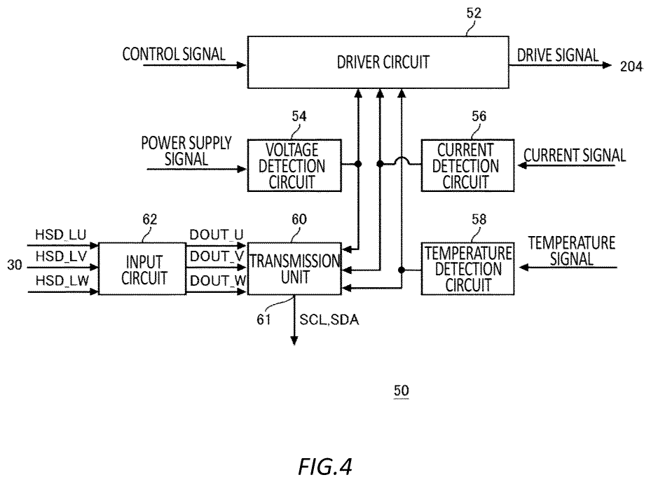

FIG. 4 is a block diagram indicating a configuration example of a low side circuit 50. The low side circuit 50 of the present example has a driver circuit 52, a voltage detection circuit 54, a current detection circuit 56, a temperature detection circuit 58, a transmission unit 60, and an input circuit 62. The driver circuit 52 outputs a drive signal that controls a power semiconductor 204 based on a control signal that is input from a controller outside, and the like.

The voltage detection circuit 54 detects a voltage at a predetermined place in the low side circuit 50. For example, the voltage detection circuit 54 may detect a first power supply voltage VH_L at a place to which the first power supply voltage VH_L is applied. The voltage detection circuit 54 may determine whether a difference between the voltage that is detected and a reference value is within an allowable range. The voltage detection circuit 54 may inform the driver circuit 52 the determination result. The driver circuit 52 may control the power semiconductor 204 to be in an OFF state when the difference between the voltage that is detected by the voltage detection circuit 54 and the reference value is not within an allowable range.

The current detection circuit 56 detects a current flowing in a predetermined place in the low side circuit 50. For example, the current detection circuit 56 may detect a current flowing from the driver circuit 52 to the power semiconductor 204. The current detection circuit 56 may determine whether a difference between the current that is detected and a reference value is within an allowable range. The current detection circuit 56 may inform the driver circuit 52 the determination result. The driver circuit 52 may control the power semiconductor 204 to be in an OFF state when the difference between the current that is detected by the current detection circuit 56 and the reference value is not within an allowable range.

The temperature detection circuit 58 detects a temperature at a predetermined place in the low side circuit 50. For example, the temperature detection circuit 58 may detect a temperature of the driver circuit 52. The temperature detection circuit 58 may determine whether a difference between the temperature that is detected and a reference value is within an allowable range. The temperature detection circuit 58 may inform the driver circuit 52 the determination result. The driver circuit 52 may control the power semiconductor 204 to be in an OFF state when the difference between the temperature that is detected by the temperature detection circuit 58 and the reference value is not within an allowable range.

The voltage detection circuit 54, the current detection circuit 56, and the temperature detection circuit 58 may detect a voltage, a current, and a temperature of an output apparatus 200. The voltage detection circuit 54, the current detection circuit 56, and the temperature detection circuit 58 may respectively detect a voltage, a current, and a temperature of a power semiconductor 204.

The transmission unit 60 generates a low side state signal indicating a state of the low side circuit 50 as a digital value based on at least one of the voltage that is detected by the voltage detection circuit 54, the current that is detected by the current detection circuit 56, and the temperature detected by the temperature detection circuit 58. The low side state signal may include information similar to the high side state signal with respect to the low side circuit 50.

One or more high side state signals HSD_L are input from a transmission unit 30 to the input circuit 62. A high side state signal HSD_LU, HSD_LV, and HSD_LW are input to the input circuit 62 of the present example. The input circuit 62 outputs digital signals DOUT_U, DOUT_V, and DOUT_W indicating information included in the high side state signal HSD_LU, HSD_LV, and HSD_LW with digital values of multiple bits.

The transmission unit 60 transmits a state signal SCL including the digital signal DOUT of the high side state signal HSD_L to an external apparatus. The transmission unit 60 of the present example outputs the digital signal DOUT of the high side state signal and a digital signal of the low side state signal, from a terminal 61 that is common. The state signals SCL and SDA may include information of both the digital signal DOUT of the high side state signal and the digital signal of the low side state signal. The state signal SCL may include the digital signal DOUT of the high side state signal and the digital signal of the low side state signal in a time-shared manner. The transmission unit 60 may output the state signal SCL to a display apparatus that displays a state of a driving apparatus 100, and may output the state signal SCL to a recording apparatus that records the state of the driving apparatus 100.

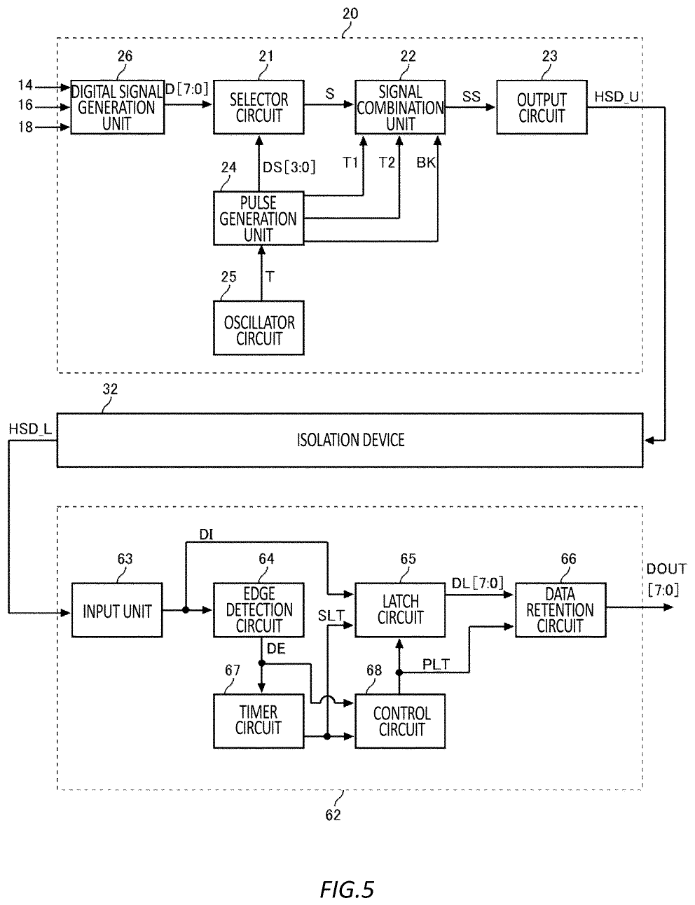

FIG. 5 is a block diagram indicating a configuration example of a state signal generation unit 20 and an input circuit 62. The state signal generation unit 20 of the present example has a digital signal generation unit 26, a selector circuit 21, a signal combination unit 22, an output circuit 23, a pulse generation unit 24, and an oscillator circuit 25. The input circuit 62 of the present example has an input unit 63, an edge detection circuit 64, a latch circuit 65, a data retention circuit 66, a timer circuit 67, and a control circuit 68.

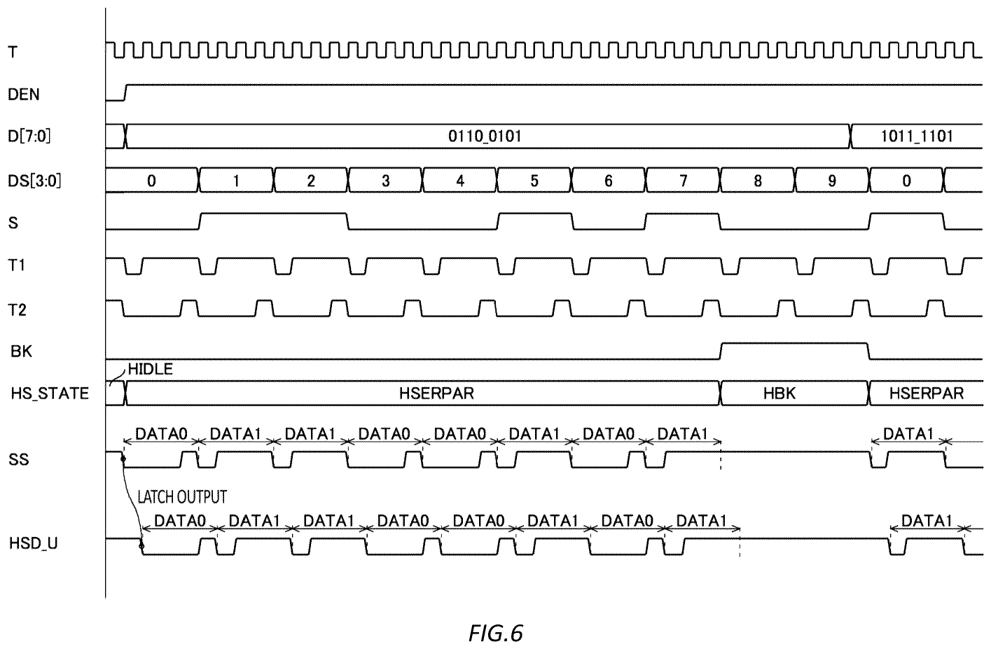

FIG. 6 is a timing chart describing an exemplary operation of the state signal generation unit 20 indicated in FIG. 5. The oscillator circuit 25 generates a clock signal T that has a predetermined cycle. Each component of the state signal generation unit 20 may be operated with the cycle of the clock signal T by the clock signal T being input thereto. In addition, an enable signal DEN indicating a start of an operation may be input to the state signal generation unit 20. In the present example, at a timing at which the enable signal DEN transits into H level from L level, the operation of the state signal generation unit 20 is started.

Detection results in one or more state detection circuits such as a voltage detection circuit 14, a current detection circuit 16, and a temperature detection circuit 18 are input to a digital signal generation unit 26. The digital signal generation unit 26 generates a digital signal D indicating the detection result that is input. The digital signal of the present example is an 8-bit signal, but a bit number of the digital signal is not limited thereto.

The digital signal D may include at least one value of the voltage, the current, and the temperature (V, A, ° C.) of a high side circuit 10, and may include a determination result obtained in at least one of the voltage detection circuit 14, the current detection circuit 16, and the temperature detection circuit 18. The digital signal generation unit 26 in the example of FIG. 6 generates a digital signal D having a logical value pattern of 0110_0101. The logical value pattern is information indicating a state of the high side circuit 10. In FIG. 6, an example in which the digital signal D has the logical value pattern is described.

The pulse generation unit 24 generates a count signal DS having a value that is increased for each predetermined period. The pulse generation unit 24 of the present example counts the number of bit periods with 4 cycles of the clock signal T as 1 bit period, and generates a count signal DS indicating a count value. The count signal DS is a signal in which a value of a next count value returns to an initial value (for example, 0) when a value increases one by one from the initial value (for example, 0) to reach a predetermined upper limit value (for example, 9).

The number of count values from the initial value of the count signal DS to the upper limit value is greater than the bit number of the digital signal D. The digital signal D of the present example is 8 bit, and therefore the number of the count values from the initial value of the count signal DS to the upper limit value is greater than or equal to nine. The number of count values of the count signal DS in the example of FIG. 6 is ten integers, i.e., zero to nine.

The selector circuit 21 outputs a digital signal S of binary value based on the digital signal D and the count signal DS. The digital signal S is a digital signal of binary value that has a waveform corresponding to the logical value pattern of the digital signal D. The digital signal S of the present example is a signal in which a signal level in each bit period transits into either of H level that corresponds to a logical value 1 or L level that corresponds to a logical value 0. The bit period is a period occupied by information of one bit in the digital signal S. In the example of FIG. 6, the bit period has a length of four times the cycle of the clock signal T.

The selector circuit 21 of the present example reads a logical value of bits corresponding to the count value of the count signal DS among respective bits of the digital signal D, to generate a digital signal S according to the logical value that is read. For example, the initial value of the count value corresponds to the most significant bit of the digital signal D, and the upper limit value of the count value corresponds to a least significant bit of the digital signal D.

In the example of FIG. 6, because the logical value of the most significant bit of the digital signal D is 0, a signal level of the digital signal S is at L level in a bit period in which the count value of the count signal DS indicates an initial value 0. Similarly, the logical values of the digital signal D correspond to each of the count values 1, 2, . . . 7 of the count signal DS are 1, 1, 0, 0, 1, 0, 1. Therefore, the signal level of each bit period of the digital signal S sequentially transits into H, H, L, L, H, L, H.

A period in which the count value of the count signal DS is 8 and 9 is a blank period. After the blank period elapses, a process for a next digital value of the digital signal D (1011_1101 in FIG. 6) is started. In the present example, the signal level of the digital signal S in the blank period is L level.

The pulse generation unit 24 generates a start pulse T1 indicating a start timing of each bit period and an end pulse T2 indicating an end timing of each bit period. The start pulse T1 of the present example is a pulse sequence that is positioned at the start timing of each bit period. As an example, a timing of a front side edge of a pulse of the start pulse T1 matches the start timing of the bit period. The end pulse T2 of the present example is a pulse sequence that is positioned at the end timing of each bit period. As an example, a timing of a rear side edge of a pulse of the end pulse T2 matches the end timing of the bit period. A pulse width of each pulse of the start pulse T1 and the end pulse T2 is smaller than half the 1 bit period. The pulse width of the present example is ¼ the 1 bit period (that is, one cycle of the clock signal T).

The pulse generation unit 24 may output a blank signal BK. The blank signal BK of the present example is a signal that is at H level during a blank period and at L level during another period.

A state signal HS_STATE in FIG. 6 is a signal indicating an operational state of the state signal generation unit 20. A state HIDLE has the enable signal DEN at L level, and indicates an idle state. A state HSERPAR indicates a state in which the enable signal DEN is at H level, and a process for the digital signal D is performed. Note that the blank signal BK is at L level in the state HSERPAR. The state HBK indicates a blank state in which the enable signal DEN is at H level and the blank signal BK is at H level. At a standby state, when the enable signal DEN transits into H level, a process for a next digital value of the digital signal D is started.

The signal combination unit 22 generates a high side state signal SS based on the digital signal S. The high side state signal SS has a plurality of bit periods corresponding to a multiple bits of the digital value of the digital signal D. In the example of FIG. 6, each bit period of the high side state signal SS is indicated with DATA0 or DATA1.

The high side state signal SS indicates a value at which the signal level of each bit period corresponds each bit of the digital value of the digital signal D. In the example of FIG. 6, DATA0 is a bit period in which the logical value is 0, and DATA1 is a bit period in which the logical value is 1.

The signal combination unit 22 of the present example generates a high side state signal SS including the start pulse T1 and the end pulse T2 and having a signal level in a period between the start pulse T1 and the end pulse T2 as a level corresponding to the digital value of the digital signal D. In the present example, the signal level in the period between the start pulse T1 and the end pulse T2 is the same as the signal level of the digital signal S. The signal combination unit 22 may insert the start pulse T1 and the end pulse T2 in the signal waveform of the digital signal S, to generate the high side state signal SS. The high side state signal SS is a signal having a same waveform pattern as that of the above-described high side state signal HSD_U. According to the present example, a start timing and an end timing of each bit period can be explicitly indicated. Therefore, in a post-stage circuit such as the input circuit 62, a digital value of a high side state signal can be sensed accurately.

Polarities of the start pulse T1 and the end pulse T2 may be inverted. A polarity of a pulse is determined by whether a front side edge between two edges is either a leading edge or a trailing edge. In the example of FIG. 6, the start pulse T1 is a pulse in which a front side edge is a trailing edge. The end pulse T2 is a pulse in which a front side edge is a leading edge. The signal combination unit 22 positions the start pulse T1 and the end pulse T2 such that a rear side edge of an end pulse T2 of a previous bit period and a front side edge of a start pulse T1 of the above bit period are common edges. By differentiating the polarities of the start pulse T1 and the end pulse T2, an edge can be always positioned at a boundary timing of each bit period. In the example of FIG. 6, in the high side state signal SS, a trailing edge is always positioned at a boundary timing of each bit period. In addition, in the high side state signal SS, the trailing edge is not positioned at timings other than the boundary timing of each bit period.

The high side state signal SS of the present example transits, from the trailing edge, into a signal level corresponding to the digital value after a pulse time of the start pulse T1 (for example, one cycle of the clock signal T) elapses. In the period of DATA0, the signal level of the high side state signal SS is maintained at L level after the pulse time of the start pulse T1 elapses. Note that the signal level of the high side state signal SS transits into H level at a timing of a front side edge of the end pulse T2. In addition, in the period of DATA1, the signal level of the high side state signal SS transits into H level when the pulse time of the start pulse T1 elapses. The signal level of the high side state signal SS is maintained at H level until the start timing of a next bit period.

In the present example, in the blank period in which the blank signal BK is at H level, the high side state signal SS is maintained at H level. That is, the signal level of the high side state signal SS in the blank period is the same as a preceding signal level of the front side edge of the start pulse T1. In this way, in the process of the next digital value of the digital signal D, the front side edge of the start pulse T1 can be positioned at a start timing of a first bit period.

The output circuit 23 output the high side state signal HSD_U based on the high side state signal SS. The high side state signal HSD_U has a same waveform pattern as that of the high side state signal SS. The high side state signal HSD_U may have a predetermined delay time for the high side state signal SS. The output circuit 23 of the present example latches a value of the high side state signal SS in the cycle of the clock signal T, to sequentially output the value as the high side state signal HSD_U. In this case, the high side state signal HSD_U is delayed for one cycle of the clock signal T for the high side state signal SS.

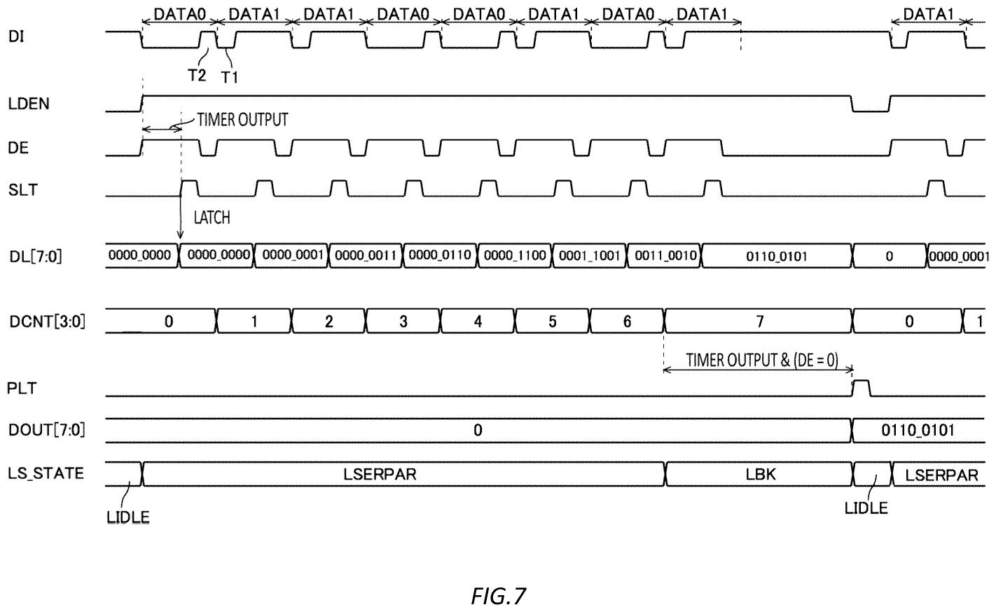

FIG. 7 is a timing chart describing an exemplary operation of the input circuit 62 indicated in FIG. 5. The input circuit 62 may operate in a same cycle as that of the clock signal T indicated in FIG. 6, or may operate in another cycle.

An enable signal LDEN indicating a start of an operation may be input to the input circuit 62. In the present example, a signal processing for a high side state signal HSD_L starts at a timing at which the enable signal LDEN transits from L level into H level.

The input unit 63 generates an input signal DI based on the high side state signal HSD_U. The input signal DI may have a same waveform pattern as that of the high side state signal HSD_U. The input unit 63 may generate the input signal DI by sampling the high side state signal HSD_U with a predetermined cycle. That is, the input signal DI is a signal that is equivalent to the high side state signal HSD_U. Herein, the input signal DI may be handled as the high side state signal HSD_U.

The input signal DI may be a digital signal of binary that has a first reference voltage GND at L level, and a first power supply voltage VH_L at H level. Similar to the high side state signal HSD_U indicated in FIG. 6, the input signal DI has a plurality of bit periods DATA0, DATA1. In addition, similar to the high side state signal HSD_U, in each bit period of the input signal DI, a start pulse T1 and an end pulse T2 are included.

The edge detection circuit 64 detects an edge that is positioned at a boundary of each bit period of the input signal DI. In this way, a start timing or an end timing of each bit period in the high side state signal HSD_L that is received from the transmission unit 30 (the input signal DI in the present example) can be extracted. The edge detection circuit 64 generates an edge detection signal DE corresponding to the edge that is detected. The edge detection signal DE is a signal indicating a start timing or an end timing of each bit period of the input signal DI.

The edge detection circuit 64 of the present example detects a trailing edge in the input signal DI. The edge detection circuit 64 generates an edge detection signal DE having an edge at a timing of the trailing edge. The edge detection signal DE of the present example has a leading edge at a timing of the trailing edge in the input signal DI. After the leading edge, the edge detection signal DE of the present example maintains H level for a maintaining period that is shorter than the 1 bit period. After the maintaining period elapses, the edge detection signal DE transits to L level. Then, the start timing of the next bit period transits to H level. In this way, a leading edge can be positioned in the edge detection signal DE, synchronously with the start timing of each bit period in the input signal DI. In the blank period after each bit period, the signal level of the edge detection signal DE in the present example maintains L level.

The timer circuit 67 generates a strobe signal SLT based on the edge detection signal DE. The strobe signal SLT is a signal in which an edge is positioned to have a predetermined delay time for the leading edge of the edge detection signal DE. The strobe signal SLT of the present example has a leading edge to have a predetermined delay time for the leading edge of the edge detection signal DE. The strobe signal SLT has a pulse in which H level is maintained for only a predetermined pulse width from the leading edge.

The pulse width is shorter than the bit period. The pulse width may be the same as the pulse width of the start pulse T1 or the end pulse T2.

The delay time is greater than the pulse width of the start pulse T1. In addition, the delay time is shorter than a time from the start timing of the bit period to the front side edge of the end pulse. That is, in each bit period, the leading edge of the strobe signal SLT of the present example is positioned in a period indicating a signal level corresponding to a logical value. The leading edge of the strobe signal SLT may be positioned in a middle of each bit period.

The latch circuit 65 detects a signal level of the input signal DI at a detection timing that is set with reference to the start timing or the end timing of each bit period of the input signal DI. The latch circuit 65 of the present example latches the signal level of the input signal DI at a timing of the leading edge of the strobe signal SLT. In this way, the latch circuit 65 can detect the signal level corresponding to a logical value of each bit period of the input signal DI. The latch circuit 65 generates a digital signal DL of multiple bits based on the signal level that is detected in each bit period. A bit number of the digital signal DL is the same as the bit number of the digital signal D (8 bits in the present example).

The latch circuit 65 of the present example sequentially inserts a logical value that is detected according to the leading edge of the strobe signal SLT to a least significant bit of the digital signal DL. The latch circuit 65 shifts a logical value of each bit of the digital signal DL toward a significant bit side by one bit before inserting the logical value to the least significant bit of the digital signal DL. By such a process, a digital signal DL corresponding to a logical value pattern of the input signal DI can be generated.

The control circuit 68 may generate a count signal DCNT obtained by counting a predetermined edge in the edge detection signal DE. The count signal DCNT is a signal in which a count value is increased one by one every time the bit period elapses. An initial value of the count signal DCNT of the present example is 0.

The control circuit 68 outputs an output control signal PLT that has a pulse at a timing at which a predetermined time elapses after a count value of the count signal DCNT reaches an upper limit value. The upper limit value of the count value of the count signal DCNT corresponds to the bit number of the digital signal DL. The upper limit value of the present example is 7. The predetermined time may be measured by the timer circuit 67. The predetermined time may be increased than the 1 bit period. In this way, after a process for a final bit of the digital signal DL ends, the pulse of the output control signal PLT can be generated. The control circuit 68 may output the pulse of the output control signal PLT when the predetermined time elapses and the edge detection signal DE is L level.

The data retention circuit 66 incorporates a digital value of the digital signal DL according to the pulse of the output control signal PLT. In this way, the data retention circuit 66 can incorporate the digital signal DL after the logical values of all the bits of the digital value (8 bits in the present example) are inserted. The data retention circuit 66 retains the digital value of the digital signal DL that is incorporated in a register and the like. The data retention circuit 66 outputs the digital value that is retained as a digital signal DOUT.

The control circuit 68 may set the count value of the count signal DCNT as an initial value at a timing of the pulse of the output control signal PLT. In this way, the count signal DCNT that is reset to be the initial value can be used in a process of a next digital value.

The latch circuit 65 may set the logical value of each bit of the digital signal DL as an initial value (for example, 0) at the timing of the pulse of the output control signal PLT. In this way, the digital signal DL that is reset to be the initial value can be used in a process of a next digital value.

A state signal LS_STATE in FIG. 7 is a signal indicating an operational state of the input circuit 62. A state LIDLE has the enable signal LDEN at L level, and indicates an idle state. A state LSERPAR indicates a state in which the enable signal LDEN is at H level, and a process for the high side state signal HSD_L is performed. The state LBK indicates a blank state in which the enable signal LDEN is at H level and the count signal DCNT is the upper limit value.

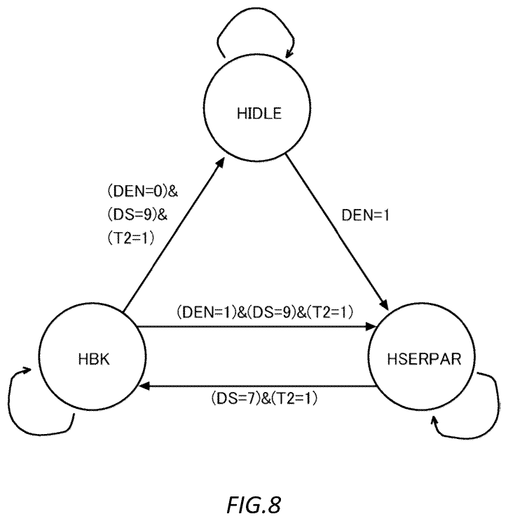

FIG. 8 is a conceptual diagram of a state machine indicating a state transition of the state signal generation unit 20. Each state HIDLE, HSERPAR, and HBK in the state machine of FIG. 8 is similar to each state described in the state signal HS_STATE of FIG. 6.

The state signal generation unit 20 is in a standby state HIDLE during the enable signal DEN is indicating 0. When the enable signal DEN transits from 0 into 1, the state signal generation unit 20 transits into a process state HSERPAR. In the process state HSERPAR, the state signal generation unit 20 performs the process for the digital signal D as described in FIG. 6.

When the count value of the count signal DS is a value corresponding to a final bit of the digital signal D (in the present example, DS=7) and the end pulse T2 occurs, the process ends until the final bit of the digital signal D. In this case, the state signal generation unit 20 transits into a blank state HBK.

The blank state HBK continues until the count value of the count signal DS becomes the upper limit value (the present example, DS=9) and the end pulse T2 occurs. At a timing in which the blank state HBK ends, when the enable signal DEN is at L level (DEN=0), the state signal generation unit 20 transits into the standby state HIDLE. At a timing in which the blank state HBK ends, when the enable signal DEN is at H level (DEN=1), the state signal generation unit 20 transits into the process state HSERPAR to perform a process for a next digital value of the digital signal D.

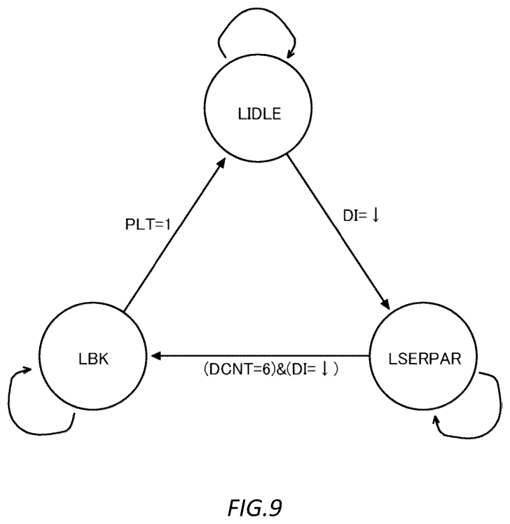

FIG. 9 is a conceptual diagram of a state machine indicating a state transition of the input circuit 62. Each state LIDLE, LSERPAR, and LBK in the state machine of FIG. 9 is similar to each state described in the state signal LS_STATE of FIG. 7.

The input circuit 62 is in a standby state LIDLE during the enable signal LDEN is indicating 0. When the enable signal LDEN transits from 0 to 1, the input circuit 62 transits into a process state LSERPAR. In the process state LSERPAR, the input circuit 62 performs the process for the high side state signal HSD_U as described in FIG. 7.

In process state LSERPAR, when the count value of the count signal DCNT becomes a preceding value of the upper limit value (DNCT=6) and a trailing edge occurs on the input signal DI, the input circuit 62 starts a process for a final bit of the input signal DI. After starting the process for the final bit, the input circuit 62 transits into the blank state HBK to maintain the count value of the count signal DCNT as the upper limit value.

The blank state HBK continues until the pulse of the output control signal PLT (PLT=1) occurs. When the pulse of the output control signal PLT occurs, the input circuit 62 transits into an idle state LIDLE. In the idle state LIDLE, when the enable signal DEN becomes H level (DEN=1), the input circuit 62 performs a process for a next digital value of the high side state signal HSD_L.

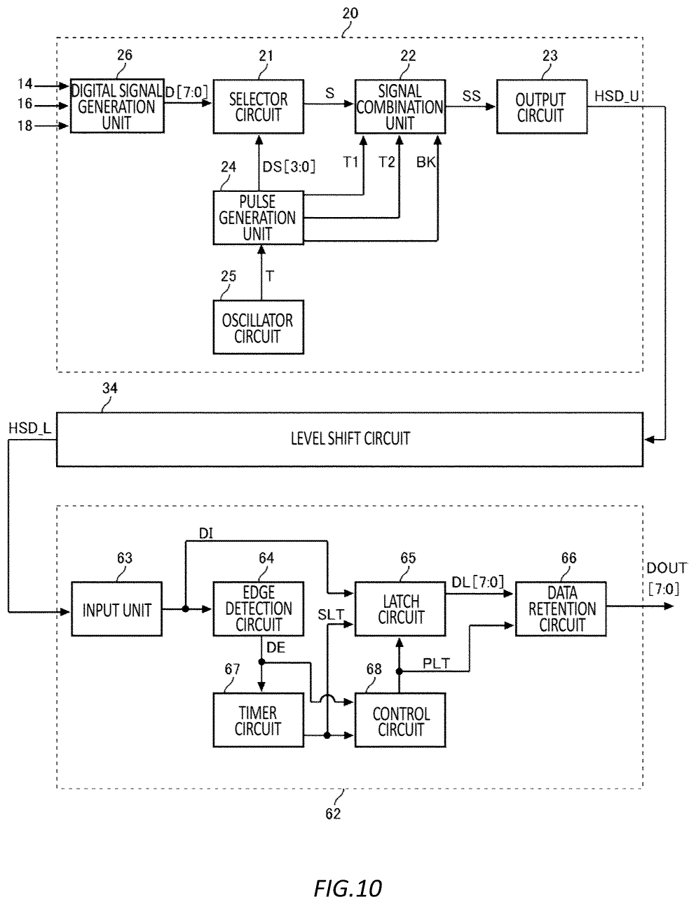

FIG. 10 shows another example of a transmission unit 30. The transmission unit 30 of the present example has a level shift circuit 34 instead of the isolation device 32 described in FIG. 1 and the like. Components other than the transmission unit 30 are the same as any aspect described herein.

The level shift circuit 34 generates a high side state signal HSD_L that is obtained by shifting a signal level of a high side state signal HSD_U according to a first reference voltage GND. The level shift circuit 34 of the present example generates a high side state signal HSD_L that is obtained by converting a second reference voltage VS of the high side state signal HSD_U into the first reference voltage GND. The level shift circuit 34 does not electrically insulate between the state signal generation unit 20 and the input circuit 62.

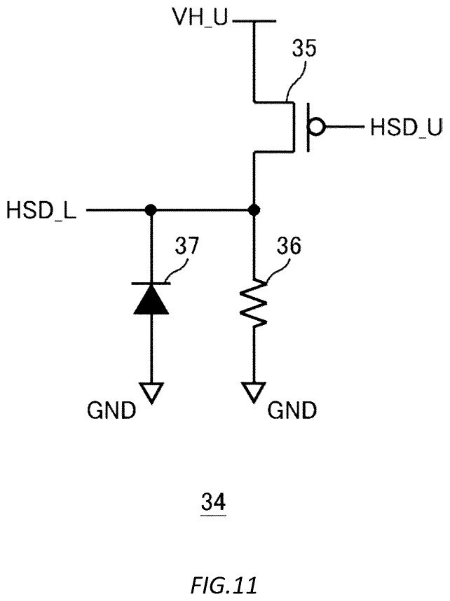

FIG. 11 shows a configuration example of a level shift circuit 34. The level shift circuit 34 of the present example has a transistor 35, a resistance 36, and a diode 37. The transistor 35 is provided between a node to which a second power supply voltage VH_U is applied and the first reference voltage GND, and the high side state signal HSD_U is input to a gate terminal. The transistor 35 of the present example is a p-channel MOSFET. The transistor 35 is turned off during a period in which the high side state signal HSD_U is at H level and turned on during a period in which the high side state signal HSD_U is at L level.

The resistance 36 is provided between a node of the first reference voltage GND and the transistor 35. In addition, the diode 37 is provided in parallel to the resistance 36 between the node of the first reference voltage GND and the transistor 35. The first reference voltage GND is applied to an anode terminal of the diode 37. The level shift circuit 34 of the present example outputs a voltage of a cathode terminal of the diode 37 as the high side state signal HSD_L.

During a period in which the high side state signal HSD_U is at H level, the transistor 35 is in OFF state. In this case, the diode 37 does not reversely conduct, and a voltage of the anode terminal becomes a predetermined voltage. In the cathode terminal of the diode 37, a first power supply voltage VH_L may be applied or another voltage may be applied. The H level of the high side state signal HSD_L may be the same as the first power supply voltage VH_L, or may be different.

During a period in which the high side state signal HSD_U is at L level, the transistor 35 is in ON state. In the cathode terminal of the diode 37, the second power supply voltage VH_U is applied. The diode 37 reversely conducts, and the voltage of the cathode terminal becomes the first reference voltage GND. In this way, the L level of the high side state signal HSD_L becomes the first reference voltage GND. According to the level shift circuit 34 of the present example, in a simple configuration, the high side state signal HSD_U can be level-shifted into the high side state signal HSD_L.

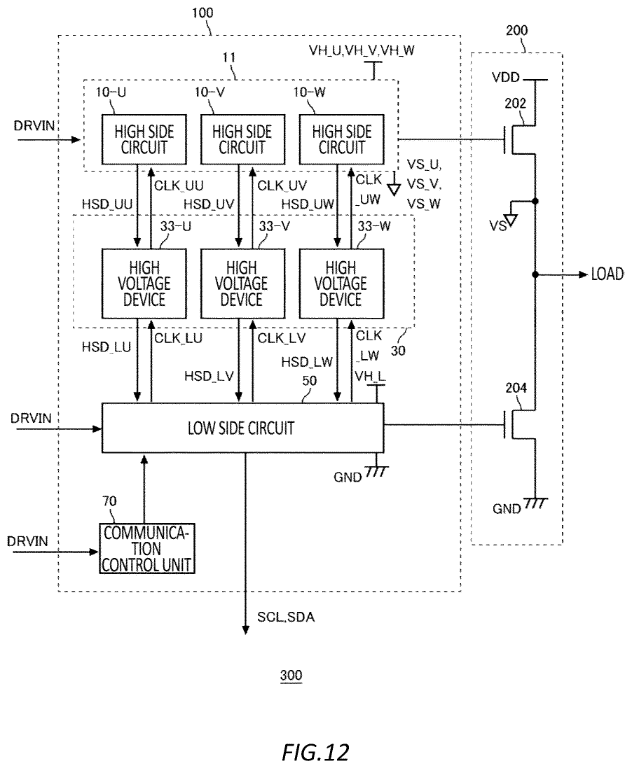

FIG. 12 shows another example of a driving apparatus 100. The driving apparatus 100 of the present invention includes a communication control unit 70. The other structures and functions are similar to those of any example described herein. When a first state signal is output from a first circuit in the driving apparatus 100 to a second circuit, the driving apparatus 100 of the present example controls an output period in which the first circuit can output the first state signal. The first state signal is a signal indicating a state of the first circuit with a digital value of multiple bits.

In the example of FIG. 12, a high side circuit unit 11 or each high side circuit 10 is the first circuit, and a low side circuit 50 is the second circuit. A high side state signal HSD_U that is output by the high side circuit 10 is an example of the first state signal. Note that the first circuit and the second circuit are not limited thereto. For example, the first circuit may be a sensor circuit that senses a temperature or a current and the like of an output apparatus 200 and the like, and outputs a first state signal corresponding to a sensing result. The second circuit may be a circuit that controls the driving apparatus 100 or the output apparatus 200 according to the sensing result in the first circuit.

The communication control unit 70 controls the above-described output period based on a loaded-state signal indicating a transition timing of ON/OFF of at least one of the power semiconductor 202 or the power semiconductor 204. Herein, the power semiconductor 202 and the power semiconductor 204 may be collectively referred to as the output apparatus 200.

The loaded-state signal is a control signal that is input to the driving apparatus 100, for example, but is not limited thereto. If a signal indicates the transition timing of the output apparatus 200, it can be used as the loaded-state signal. For example, a gate signal that is input to a gate terminal of the output apparatus 200 may be the loaded-state signal. In the present example, the control signal may be referred to as DRVIN.

At a timing at which the state of ON/OFF of the output apparatus 200 transits, a voltage and a current in a predetermined node of the output apparatus 200 greatly vary. A variation of the voltage and the current in the output apparatus 200 may affect a signal transmission in the driving apparatus 100. For example, when a common power supply voltage or reference voltage is applied to the output apparatus 200 and the driving apparatus 100, a power supply voltage or a reference voltage in the driving apparatus 100 may vary by a variation of the voltage and the current of the output apparatus 200. In addition, even if the power supply voltage or the reference voltage is not common, a radiated noise obtained by the variation of the voltage and the current in the output apparatus 200 may also affect the signal transmission in the driving apparatus 100.

The communication control unit 70 of the present example stops the output of the high side state signal HSD_U from the high side circuit 10 from a timing at which the ON/OFF of the output apparatus 200 transits until a predetermined stop period elapses. The communication control unit 70 permits output of the high side state signal HSD_U from the high side circuit 10 after the stop period elapses. In this way, the effect of switching the output apparatus 200 can be reduced, to accurately transmit the high side state signal HSD_U from the high side circuit 10 to the low side circuit 50. The stop period may be preset by a manufacturer or a user of the driving apparatus 100. The stop period may be longer than a period from a start of the switching of the output apparatus 200 until the voltage or the current of the output apparatus 200 becomes stable.

The high side circuit 10 of the present example outputs the high side state signal HSD_U according to a clock signal CLK_U that is input from the low side circuit 50. The high side circuit 10 outputs the high side state signal HSD_U during a period in which the clock signal CLK_U is input, and does not output the high side state signal HSD_U during a period in which the clock signal CLK_U is not input.

The communication control unit 70 of the present example controls an input period in which the clock signal CLK_U is input from the low side circuit 50 to the high side circuit 10 based on the control signal DRVIN. The communication control unit 70 may control an input of the clock signal CLK_U to the high side circuit 10 by controlling an output of a clock signal CLK_L from the low side circuit 50. In this way, whether the high side state signal HSD_U can be output from the high side circuit 10 can be controlled.

The transmission unit 30 of the present example has a function of transmitting the clock signal CLK in addition to functions described in FIG. 1 to FIG. 11. The transmission unit 30 has one or more high voltage devices 33 provided in response to respective high side circuits 10.

As described in FIG. 1 to FIG. 11, each high voltage device 33 converts a reference voltage of the high side state signal HSD_U from the high side circuit 10 into the first reference voltage GND of the low side circuit 50. The high voltage device 33 transmits a high side state signal HSD_L, which is obtained by converting the reference voltage, to the low side circuit 50. In addition, each high voltage device 33 converts a reference voltage of the clock signal CLK_L from the low side circuit 50 into a second reference voltage VS of the high side circuit 10. The high voltage device 33 transmits a clock signal CLK_U, which is obtained by converting the reference voltage, to the high side circuit 10. The high voltage device 33 may be a device similar to the isolation device 32 of the examples in FIG. 1 to FIG. 11, or may be a device of another structure.

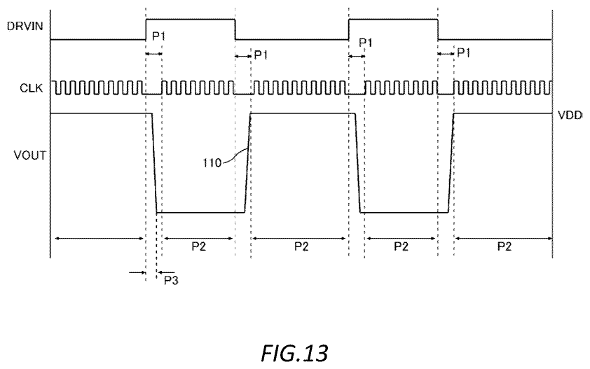

FIG. 13 shows an example of signal waveforms of a control signal DRVIN, a clock signal CLK, and an output voltage VOUT. The clock signal CLK is a clock signal CLK_L that is output from the low side circuit 50, or a clock signal CLK_U that is input to the high side circuit 10. The clock signal CLK_L and the clock signal CLK_U have time waveforms that are synchronized with each other. The output voltage VOUT is a voltage that is output to a load from the output apparatus 200.

In accordance with a transition of a logical value of the control signal DRVIN, the output apparatus 200 is switched. In accordance with the switching of the output apparatus 200, the output voltage VOUT of the output apparatus 200 transits between H level and L level. As described above, a variation of the output voltage VOUT may affect the signal transmission in the driving apparatus 100.

The communication control unit 70 of the present example stops the input of the clock signal to the high side circuit 10 from a transition timing of the control signal DRVIN until a predetermined stop period P1 elapses. In this way, the output of the high side state signal HSD_U from the high side circuit 10 in the stop period P1 can be stopped. The communication control unit 70 permits the input of the clock signal to the high side circuit 10 during an output period P2 that is from a timing at which the stop period P1 elapses until a next transition timing of the control signal DRVIN. By such a control, the effect of switching the output apparatus 200 can be reduced, to accurately transmit the high side state signal HSD_U.

The communication control unit 70 may control a length of the stop period P1 according to a characteristic of the output apparatus 200 (that is, the power semiconductor 202 and 204). The characteristic of the output apparatus 200 may be a characteristic that affects a length of a transient period P3 that is from a timing at which the control signal DRVIN transits until the output voltage VOUT becomes stable.

The communication control unit 70 may make the stop period P1 to be longer than the transient period P3. In this way, the high side state signal HSD_U can be transmitted with further accuracy. On the other hand, if the stop period P1 is too long, a period in which the high side state signal HSD_U can be transmitted becomes short. The stop period P1 may be smaller than or equal to twice the transient period P3. The communication control unit 70 may control the stop period P1 based on the length of the transient period P3.

The communication control unit 70 may control the length of the stop period P1 according to a gradient (that is, a time differential value dV/dt of a voltage) of an edge 110 of the output voltage VOUT. The edge 110 may be a leading edge or may be a trailing edge. The edge 110 may be one that has a smaller gradient among the leading edge or the trailing edge. The smaller the gradient of the edge 110 is, the longer the transient period P3 is. The communication control unit 70 may increase the stop period P1 as the gradient of the edge 110 decreases.

The communication control unit 70 may control the length of the stop period P1 according to a magnitude of a power supply voltage VDD of the output apparatus 200. The greater the power supply voltage VDD is, the longer the transient period P3 is. The communication control unit 70 may increase the stop period P1 as the power supply voltage VDD increases.

The communication control unit 70 may control the length of the stop period P1 according to a capacity of a load that is connected to the output apparatus 200. The greater the capacity of the load is, the longer the transient period P3 is. The communication control unit 70 may increase the stop period P1 as the capacity of the load increases.

The low side circuit 50 may control a cycle of the clock signal CLK_L according to a length of the output period P2. The length of the output period P2 may be a length of the output period P2 when the control signal DRVIN is indicating logic H, may be a length of the output period P2 when the control signal DRVIN is indicating logic L, or may be a length of a shorter one.

By providing the stop period P1, the output period P2 is reduced, and a pulse number of the clock signal CLK included in the output period P2 decreases. The high side circuit 10 outputs the high side state signal HSD_U according to a pulse of the clock signal CLK. Therefore, if the pulse number of the clock signal CLK included in the output period P2 decreases, a bit number that can be transmitted during one output period P2 decreases. The low side circuit 50 may reduce a cycle of the clock signal CLK_L as the output period P2 decreases. The low side circuit 50 may control the cycle of the clock signal CLK_L such that the pulse of the clock signal CLK_L of greater than or equal to a set value is included in one output period P2. In this way, in one output period P2, the high side state signal HSD_U of the bit number that is set can be transmitted.

The high side circuit 10 may control a content of data included in the high side state signal HSD_U according to the length of the output period P2. The high side circuit 10 may decrease data to be included in the high side state signal HSD_U as the output period P2 is shorter. For example, the high side circuit 10 may select, according to the length of the output period P2, the number of detection results to be included in the high side state signal HSD_U among the voltage detection result, the current detection result, and the temperature detection result described in FIG. 3.

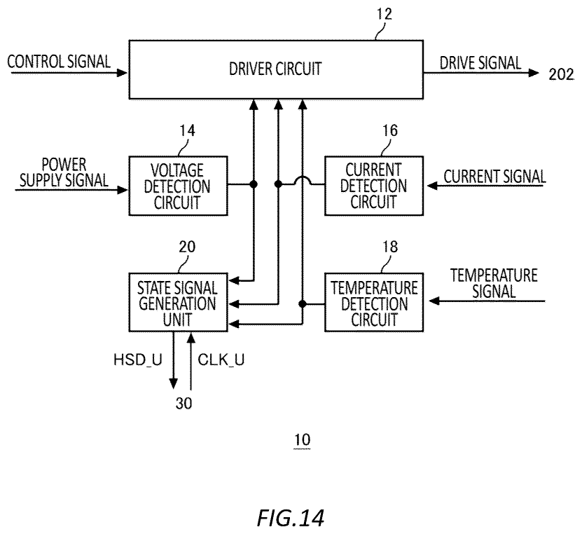

FIG. 14 is a block diagram indicating a configuration example of the high side circuit 10 indicated in FIG. 12. The high side circuit 10 of the present example has a similar configuration as that of the high side circuit 10 indicated in FIG. 3. Note that the clock signal CLK_U from the low side circuit 50 is input to a state signal generation unit 20 of the present example. The state signal generation unit 20 outputs the high side state signal HSD_U according to a pulse of the clock signal CLK_U. Therefore, by controlling the clock signal CLK_U, whether the high side state signal USD_U can be output can be controlled.

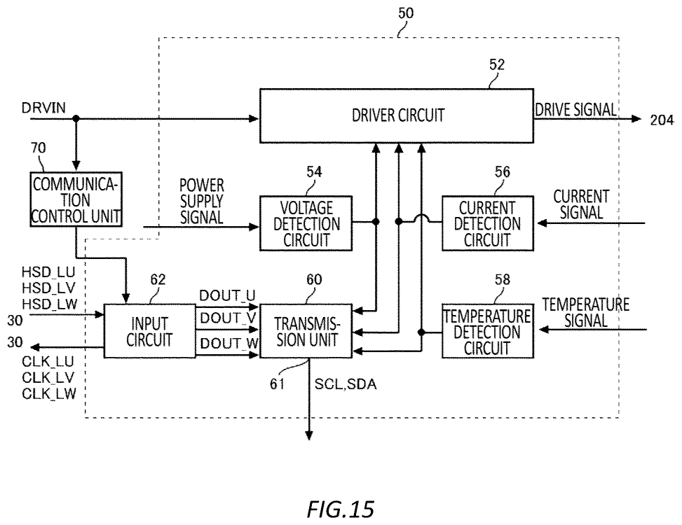

FIG. 15 is a block diagram indicating a configuration example of the low side circuit 50 indicated in FIG. 12. The low side circuit 50 of the present example has a similar configuration as that of the low side circuit 50 indicated in FIG. 4. Note that an input circuit 62 in the present example is an input/output circuit in which the high side state signal HSD_L is input and the clock signal CLK_L is output. The communication control unit 70 controls whether the clock signal CLK_L in the input circuit 62 can be output. As described above, by controlling the clock signal CLK_L, whether the high side state signal USD_U can be output can be controlled.

The communication control unit 70 of the present example is provided outside the low side circuit 50. In another example, the communication control unit 70 may be provided inside the low side circuit 50. The input circuit 62 may function as the communication control unit 70. The communication control unit 70 may operate with a reference voltage of the low side circuit 50.

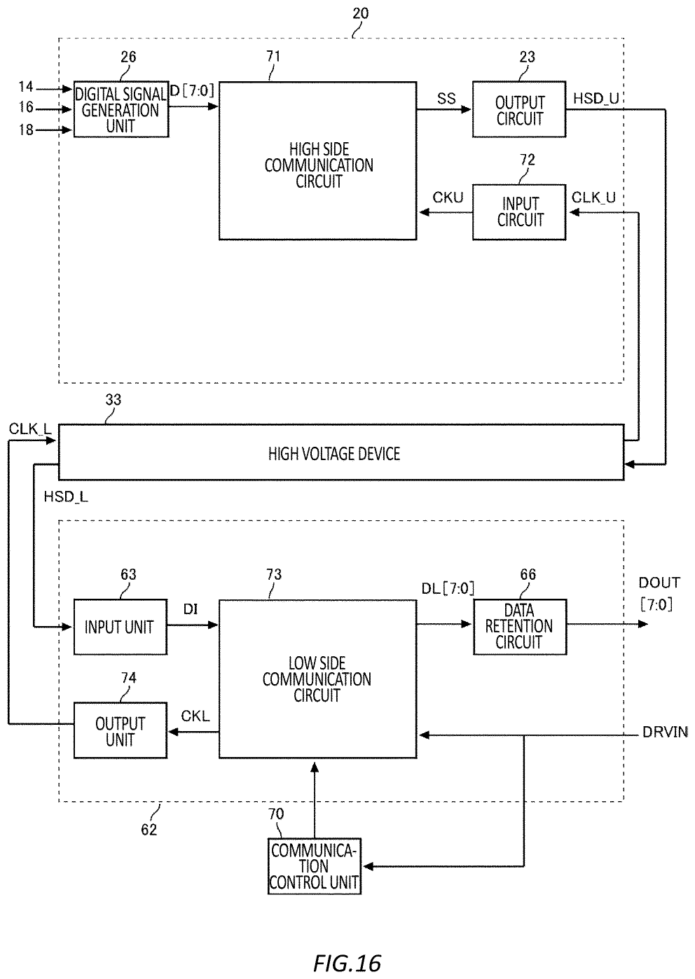

FIG. 16 is a block diagram indicating a configuration example of the state signal generation unit 20 and the input circuit 62 in the driving apparatus 100 indicated in FIG. 12 to FIG. 15. The state signal generation unit 20 of the present example further has an input circuit 72 with respect to the configuration of the state signal generation unit 20 indicated in FIG. 5. Note that in FIG. 16, the selector circuit 21, the signal combination unit 22, the pulse generation unit 24, and the oscillator circuit 25 that are indicated in FIG. 5 are collectively referred to as a high side communication circuit 71. The high side communication circuit 71 may further include another configuration.

The clock signal CLK_U is input to the input circuit 72, and the input circuit 72 outputs an internal clock signal CKU. The internal clock signal CKU may have a same pulse pattern as that of the clock signal CLK_U. Each component of the high side communication circuit 71 may operate according to a pulse of the internal clock signal CKU. In this way, the high side communication circuit 71 outputs a high side state signal SS during a period in which the clock signal CLK_U is input and stops generating and outputting the high side state signal SS when the input of the clock signal CLK_U stops.

An input circuit 62 of the present example further has an output unit 74 with respect to the configuration of the input circuit 62 indicated in the FIG. 5. Note that in FIG. 16, the edge detection circuit 64, the latch circuit 65, the timer circuit 67, and the control circuit 68 indicated in FIG. 5 are collectively referred to as a low side communication circuit 73. The low side communication circuit 73 of the present example further has a configuration that outputs the internal clock CKL to the output unit 74.

The communication control unit 70 controls whether the internal clock CKL can be output from the low side communication circuit 73 to the output unit 74. The communication control unit 70 may be provided in the low side communication circuit 73.

The output unit 74 outputs the clock signal CLK_L according to the internal clock CKL. The clock signal CLK_L may have a same pulse pattern as that of the internal clock CKL. By such a configuration, a period in which the high side communication circuit 71 outputs the high side state signal SS can be controlled by using the clock signal CLK_L.

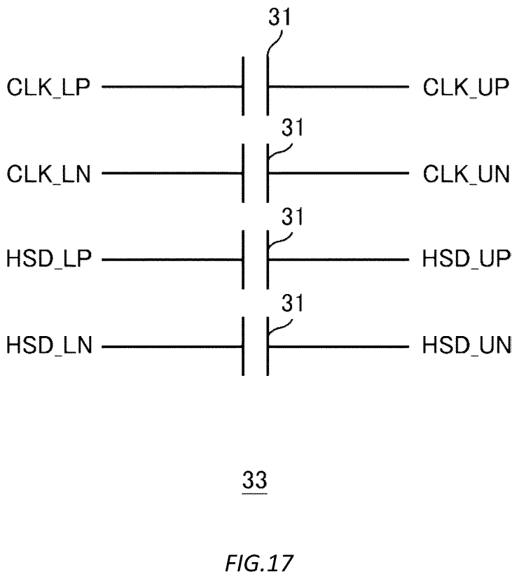

FIG. 17 shows an example of a high voltage device 33. The high voltage device 33 of the present example has a capacitor 31 that is provided between the high side circuit 10 and the low side circuit 50. The high voltage device 33 has a capacitor 31 for each signal that should be transmitted. The high voltage device 33 of the present example has a capacitor 31 for each of the clock signal CLK and a high side signal HSD. In the example of FIG. 17, each of the clock signal CLK and the high side signal HSD is a differential signal. In this case, for each of the clock signal CLK and the high side signal HSD, two capacitors 31 are provided. A capacity of each capacitor 31 may be less than 1 pF. The capacity of the capacitor 31 may be greater than 0.05 pF.

By using the capacitor 31 in the transmission unit 30, a circuit cost can be reduced. On the other hand, by using the capacitor 31, the transmission unit 30 can be easily affected by the operation of an output apparatus 200. In the present example, because the transmission of the high side state signal HSD stops according to a transition timing of the output apparatus 200, the high side state signal HSD and the clock signal CLK can be accurately transmitted while using the transmission unit 30 of low cost.

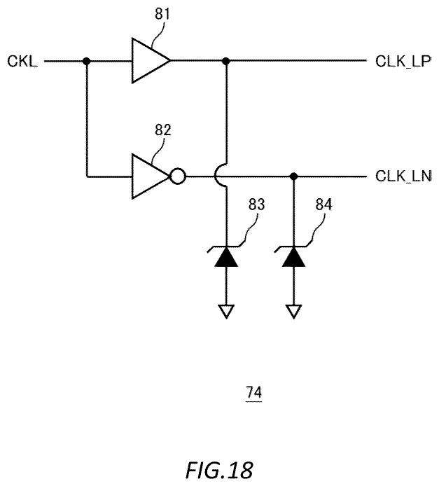

FIG. 18 shows an example of an output unit 74. The output unit 74 of the present example has a buffer 81, an inverter 82, a diode 83, and a diode 84. The buffer 81 outputs the internal clock CKL as a clock signal CLK_LP. The inverter 82 inverts a logical value of the internal clock CKL and outputs the value as a clock signal CLK_LN. The diode 83 clamps a voltage in an output end of the buffer 81 to be smaller than or equal to a constant voltage. The diode 84 clamps a voltage in an output end of the inverter 82 to be smaller than or equal to a constant voltage. By such a configuration, the output unit 74 outputs differential clock signals CLK_LP and CLK_LN. Note that the output circuit 23 may also have a similar configuration as that of the output unit 74. In the output circuit 23, the high side state signal SS is input to the buffer 81 and the inverter 82, and differential high side state signals HSD_UP, HSD_UN are output.

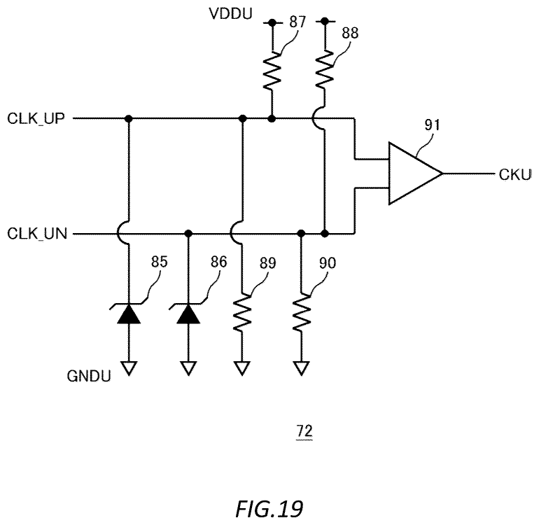

FIG. 19 shows an example of an input circuit 72. The input circuit 72 generates an internal clock CKU from differential clock signals CLK_UP and CLK_UN. The input circuit 72 of the present example has a differential circuit 91, a pull-up resistor 87, a pull-up resistor 88, a diode 85, a diode 86, a pull-down resistor 89, and a pull-down resistor 90.

The differential circuit 91 outputs the internal clock CKU according to a difference between the clock signal CLK_UP and the CLK_UN. In this way, a common mode noise can be removed. The pull-up resistor 87 connects a transmission path of the clock signal CLK_UP to a high potential VDDU. The pull-down resistor 89 connects the transmission path to a reference voltage GNDU. The diode 85 clamps a voltage of the transmission path to be smaller than or equal to a constant voltage. The pull-up resistor 88 connects a transmission path of the clock signal CLK_UN to a high potential VDDU. The pull-down resistor 90 connects the transmission path to a reference voltage GNDU. The diode 86 clamps a voltage of the transmission path to be smaller than or equal to a constant voltage. Note that the input unit 63 may also have a similar configuration as that of the input circuit 72. In the input unit 63, a high side state signal HSD_L is input instead of the clock signal CLK_U, and an input signal DI is output instead of the internal clock CKU. In addition, in the input unit 63, a high potential VDDL and a reference potential GNDL of the low side circuit 50 are applied instead of the high potential VDDU and the reference voltage GNDU of the high side circuit 10.

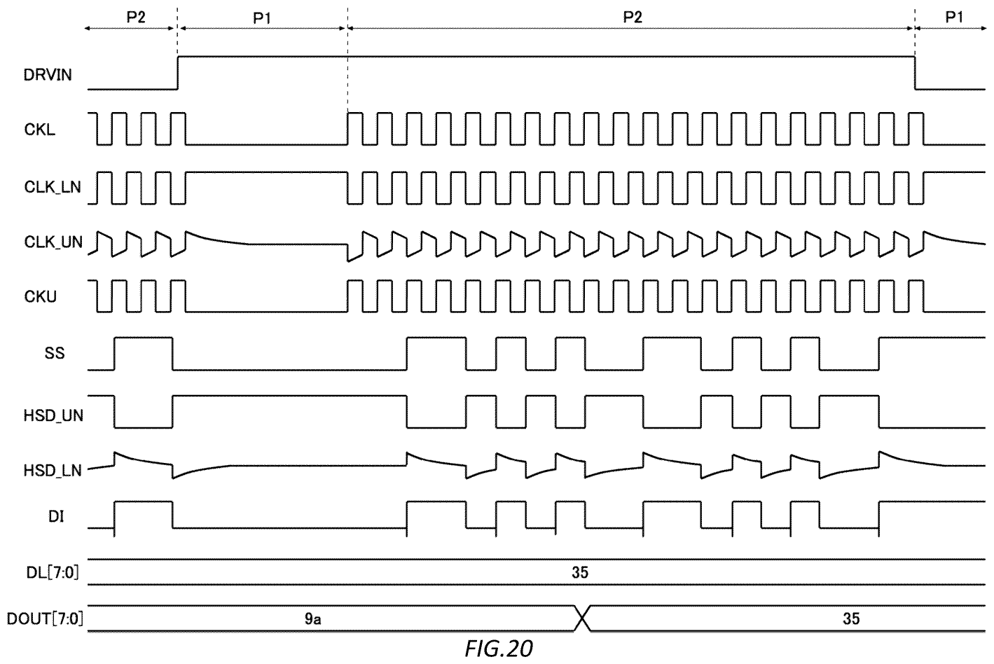

FIG. 20 shows an example of a time waveform of each signal in the driving apparatus 100. In FIG. 20, only one waveform (N side) of the differential signal is indicated. As described above, the communication control unit 70 stops an output of the internal clock CKL in the low side communication circuit 73 from the transition timing of the control signal DRVIN until the stop period P1 elapses. In this way, in the stop period P1, the clock signal CLK_LN and the clock signal CLK_UN do not have pulses. In FIG. 20, a waveform of the clock signal CLK_UN is dull due to the capacitor 31.

The internal clock CKU of the high side circuit 10 has a same pulse pattern as that of the clock signal CLK_UN. Note that a waveform of the internal clock CKU is shaped by the input circuit 72.

The high side communication circuit 71 outputs the high side state signal SS according to a pulse of the internal clock CKU. The high side state signal SS of the present example is a signal in which a pulse width is modulated according to a value of information that should be conveyed. The high side state signal SS does not have a pulse in the stop period P1. Similarly, the high side state signals HSD_UN and LN do not have pulses in the stop period P1. In FIG. 20, a waveform of a high side state signal HSD_LN is dull due to the capacitor 31.

The input unit 63 outputs an input signal DI obtained by shaping the waveform of the high side state signal HSD_LN. The low side communication circuit 73 outputs the input signal DI after converting it into a digital signal DL. The low side communication circuit 73 may output the digital signal DL also in the stop period P1. A data retention circuit 66 outputs a digital signal DOUT corresponding to the digital signal DL.

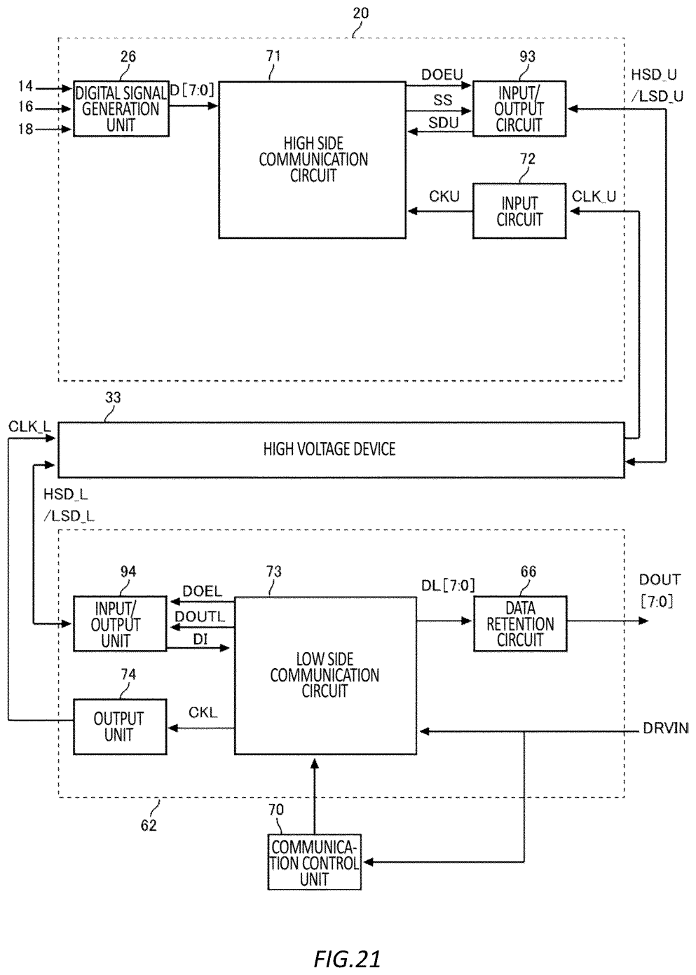

FIG. 21 is a block diagram indicating another configuration example of the state signal generation unit 20 and the input circuit 62 in the driving apparatus 100 indicated in FIG. 12 to FIG. 15. The state signal generation unit 20 of the present example has an input/output circuit 93 instead of the output circuit 23. The input circuit 62 of the present example has an input/output unit 94 instead of the input unit 63. The other components are similar to those of any example described in FIG. 12 to FIG. 20.

The input/output circuit 93 and the input/output unit 94 of the present example transmit signals bidirectionally to each other. The input/output circuit 93 outputs a high side state signal HSD_U according to a high side state signal SS similar to the examples of FIG. 12 to FIG. 20. In addition, a low side signal LSD_U is input to the input/output circuit 93 of the present example from a low side circuit 50. The input/output circuit 93 generates an input signal SDU according to the low side signal LSD_U, and inputs it to the high side communication circuit 71. The low side signal LSD_U may be a signal for controlling operation of a high side circuit 10.

In the input/output circuit 93, an output control signal DOEU may be input, which switches between outputting the high side state signal HSD_U corresponding to the high side state signal SS or outputting the input signal SDU corresponding to a low side signal LSD. The output control signal DOEU may be generated by a high side communication circuit 71.

The input/output unit 94 outputs an input signal DI according to the high side state signal HSD_L similar to the examples of FIG. 12 to FIG. 20. In addition, the input/output unit 94 of the present example outputs a low side signal LSD_L corresponding to a low side signal DOUTL.

In the input/output unit 94, an output control signal DOEL may be input, which switches between outputting the low side signal LSD_L corresponding to the low side signal DOUTL or outputting the high side state signal HSD_U corresponding to the high side state signal SS. The low side signal LSD_L and the output control signal DOEL may be generated by the low side communication circuit 73. In the stop period P1, the communication control unit 70 may stop the output of the low side signal LSD_L by making a logical value of an output control signal DOUEL to be logic L. Alternatively, in the stop period P1, the communication control unit 70 may stop the output of the low side signal DOUTL from the low side communication circuit 73.

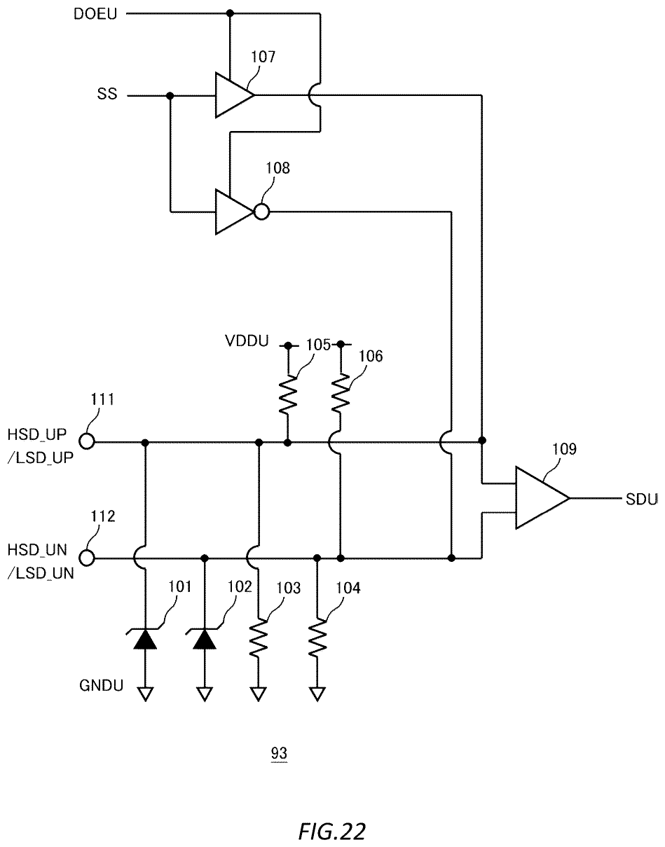

FIG. 22 shows an example of an input/output circuit 93. An input/output circuit 93 of the present example has a buffer 107, an inverter 108, a diode 101, a diode 102, a pull-up resistor 105, a pull-up resistor 106, a pull-down resistor 103, a pull-down resistor 104, a differential circuit 109, an input/output terminal 111, and an input/output terminal 112.

The pull-up resistor 105 connects the input/output terminal 111 to a high potential VDDU. The pull-down resistor 103 connects the input/output terminal 111 to a reference voltage GNDU. The diode 101 clamps a voltage of the input/output terminal 111 to be smaller than or equal to a constant voltage.

The pull-up resistor 106 connects the input/output terminal 112 to a high potential VDDU. The pull-down resistor 104 connects the input/output terminal 112 to a reference voltage GNDU. The diode 102 clamps a voltage of the input/output terminal 112 to be smaller than or equal to a constant voltage.

The buffer 107 outputs a high side state signal SS. The inverter 108 outputs a signal obtained by inverting the high side state signal SS. Note that a control signal DOEU is input to power supply terminals of the buffer 107 and the inverter 108. When the control signal DOEU indicates logic L (a reference potential), the buffer 107 and the inverter 108 output high impedance regardless of the logical value of the high side state signal SS.

When the control signal DOUE indicates logic H, the buffer 107 outputs a high side signal HSD_UP corresponding to the high side state signal SS to the input/output terminal 111. When the control signal DOUE indicates logic H, the inverter 108 outputs a high side signal HSD_UN that is obtained by inverting the high side state signal SS to the input/output terminal 112. In this case, the differential circuit 109 may output an input signal SDU corresponding to a difference between the high side state signal SS and an inverted signal of the high side state signal SS.

When the control signal DOUE indicates logic L, a low side signal LSD_UP and a low side signal LSD_UN are input to the differential circuit 109 via the input/output terminal 111 and the input/output terminal 112. In this case, the differential circuit 109 outputs an input signal SDU corresponding to a difference between the low side signal LSD_UP and the low side signal LSD_UN.

The input/output unit 94 may also have a similar configuration as that of the input/output circuit 93 in FIG. 22. In the input/output unit 94, the low side signal DOUTL and the control signal DOEL are input instead of the high side state signal SS and the control signal DOEU, and the input signal DI is output instead of the input signal SDU. In addition, a high side signal HSD_LP is input to the input/output terminal 111, and a low side signal LSD_LP is output from t the input/output terminal 111. A high side signal HSD_LN is input to the input/output terminal 112, and a low side signal LSD_LN is output from the input/output terminal 112.

While the present invention has been described with the embodiments, the technical scope of the present invention is not limited to the above-described embodiments. It is apparent to persons skilled in the art that various alterations or improvements can be added to the above-described embodiments. It is also apparent from the description of the claims that the embodiments to which such alterations or improvements are made can also fall within the technical scope of the present invention.

What is claimed is:

1. A driving apparatus of a power semiconductor, comprising:
a first circuit;
a second circuit;
a state signal generation unit that generates a first state signal indicating a state of the first circuit with a digital value of multiple bits; and
a communication control unit that controls an output period in which the first circuit outputs the first state signal based on a loaded-state signal indicating a transition timing of ON/OFF of the power semiconductor.

2. The driving apparatus according to claim 1, wherein the communication control unit permits output of the first state signal after a predetermined stop period elapses from a timing at which the ON/OFF of the power semiconductor transits.

3. The driving apparatus according to claim 1, wherein
the first circuit outputs the first state signal according to a clock signal that is input from the second circuit, and
the communication control unit controls an input period at which the clock signal is input from the second circuit to the first circuit based on the loaded-state signal.

4. The driving apparatus according to claim 2, wherein the communication control unit controls the stop period according to a characteristic of the power semiconductor.

5. The driving apparatus according to claim 2, wherein the communication control unit controls the stop period according to a magnitude of a power supply voltage that is applied to the power semiconductor.

6. The driving apparatus according to claim 2, wherein the communication control unit controls the stop period according to a capacity of a load that is connected to the power semiconductor.

7. The driving apparatus according to claim 3, wherein the second circuit controls a cycle of the clock signal according to a length of the output period.

8. The driving apparatus according to claim 1, wherein
the first circuit is a low side circuit that operates with a first reference voltage, and
the second circuit is a high side circuit that operates with a second reference voltage that is higher than the first reference voltage, and the driving apparatus further comprises:
a transmission unit that transmits, by converting a reference voltage of the first state signal according to the first reference voltage, the first state signal, which is obtained by converting the reference voltage, to the low side circuit.

9. The driving apparatus according to claim 8, wherein the transmission unit has a capacitor that is provided between the high side circuit and the low side circuit.

10. A driving apparatus of a power semiconductor, comprising:
a low side circuit that operates with a first reference voltage,
a high side circuit that operates with a second reference voltage that is higher than the first reference voltage,
a state signal generation unit that generates a high side state signal indicating a state of the high side circuit with a digital value of multiple bits, and
a transmission unit that transmits, by converting a reference voltage of the high side state signal according to the first reference voltage, the high side state signal, which is obtained by converting the reference voltage, to the low side circuit.

11. The driving apparatus according to claim 10, wherein the low side circuit has a transmission unit that transmits the high side state signal to an outside.

12. The driving apparatus according to claim 11, wherein
the low side circuit generates a low side state signal indicating a state of the low side circuit with a digital value, and
the transmission unit outputs the high side state signal and the low side state signal from a common terminal.

13. The driving apparatus according to claim 10, wherein the transmission unit includes an isolation device that transmits the high side state signal in a state in which the high side circuit and the low side circuit are electrically insulated.

14. The driving apparatus according to claim 10, wherein the transmission unit has a level shift circuit that converts a signal level of the high side state signal according to the first reference voltage.

15. The driving apparatus according to claim 10, wherein the high side state signal has a plurality of bit periods corresponding to the multiple bits of the digital value, and a signal level of each bit period indicates a value corresponding to a value of each bit of the digital value.

16. The driving apparatus according to claim 15, wherein the state signal generation unit includes:
a pulse generation unit that generates a start pulse indicating a start timing of each of the bit periods and an end pulse indicating an end timing of each of the bit periods; and
a signal combination unit that generates the high side state signal including the start pulse and the end pulse and having a signal level in a period between the start pulse and the end pulse as a level corresponding to the digital value.

17. The driving apparatus according to claim 16, wherein the start pulse and the end pulse have polarities that are inverted to each other.

18. The driving apparatus according to claim 16, wherein the low side circuit extracts the start timing or the end timing of each of the bit period in the high side state signal that is received from the transmission unit, and detects a signal level of the high side state signal at a preset detection timing with reference to the start timing or the end timing.

19. The driving apparatus according to claim 10, further comprising a communication control unit that controls a period in which the high side circuit outputs the high side state signal based on a loaded-state signal indicating a transition timing of ON/OFF of the power semiconductor.

20. The driving apparatus according to claim 19, wherein the communication control unit permits output of the high side state signal after a predetermined period elapses from a timing at which the ON/OFF of the power semiconductor transits.

21. The driving apparatus according to claim 19, wherein
the high side circuit outputs the high side state signal according to a clock signal that is input from the low side circuit, and
the communication control unit controls a period at which the clock signal is input from the low side circuit to the high side circuit based on the loaded-state signal.
